(19) United States
(12) Patent Application Publication
(10) Pub. No.: US 2017/0213924 A1
(43) Pub. Date: Jul. 27, 2017

(54) QUANTUM DOT SOLAR CELL

(71) Applicant: KYOCERA Corporation, Kyoto-shi, Kyoto (JP)

(72) Inventors: Shintaro KUBO, Kirishima-shi (JP); Toru NAKAYAMA, Kirishima-shi (JP); Hisakazu NINOMIYA, Kirishima-shi (JP); Kazuya MURAMOTO, Kirishima-shi (JP); Kohei FUJITA, Kirishima-shi (JP)

(73) Assignee: KYOCERA Corporation, Kyoto-shi, Kyoto (JP)

(21) Appl. No.: 15/326,050

(22) PCT Filed: Jul. 30, 2015
(86) PCT No.: PCT/JP2015/071668

§ 371 Date: Jan. 13, 2017

(30) Foreign Application Priority Data
Jul. 30, 2014 (JP) 2014-155085

(51) Int. Cl. H01L 31/0352; C01G 21/21; C01B 19/00; C01B 33/021

(52) U.S. Cl. CPC H01L 31/035218; C01B 33/021; C01G 21/21; C01B 19/007; H01L 31/035281; C01P 2004/32; C01P 2004/30; C01P 2004/16; C01P 2006/40; C01P 2004/64; B82Y 40/00

(57) ABSTRACT

There is provided a quantum dot solar cell having a high optical absorption coefficient. The quantum dot solar cell includes a quantum dot layer 3 including a plurality of quantum dots 1, wherein the quantum dot layer 3 includes a first quantum dot layer 3A having an index σ/x of 5% or more, wherein x is an average particle size, and σ is a standard deviation. The quantum dot layer 3 also includes a second quantum dot layer 3B that is provided on the light entrance surface 3b and/or the light exit surface 3c of the first quantum dot layer 3A and has an average particle size and an index σ/x smaller than those of the first quantum dot layer 3A.

### TECHNICAL FIELD

The present invention relates to a solar cell using quantum dots.

### BACKGROUND ART

In recent years, it has been proposed to use quantum dots for photoelectric converters such as solar cells and semiconductor lasers. Quantum dots are generally about 10 nm-sized nanoparticles composed mainly of a semiconductor material. In such a small-sized semiconductor material, electrons can be confined three-dimensionally, and the density of states can have δ-function-like discrete levels. Therefore, when generated in quantum dots, carriers can concentrate at discrete energy levels for band structure, so that the quantum dots can absorb light (sunlight) at wavelengths corresponding to a plurality of band gaps. Therefore, it is considered that solar cells using quantum dots can absorb light in a wider range of wavelengths and thus have higher photoelectric conversion efficiency.

The band gap of quantum dots is known to depend on the composition or size of the material used to form them. The present applicant has previously found that when variations in the particle size of quantum dots are reduced, wave functions between quantum dots can overlap, so that the carrier transport efficiency can be improved (see, for example, Patent Document 1).

FIG. 8(a) is a cross-sectional view schematically showing the quantum dot solar cell disclosed in Patent Document 1, and FIG. 8(b) is an exemplary graph showing the optical absorption properties of the quantum dot solar cell of FIG. 8(a). In FIG. 8(a), reference numeral 101 represents a quantum dot, 103 a quantum dot layer, 105 a transparent conductive film, 107 a glass substrate, and 109 a metal electrode.

### RELATED ART DOCUMENT

### Patent Document

Patent Document 1: JP 2013-229378 A

### SUMMARY OF THE INVENTION

### Problems to be Solved by the Invention

Unfortunately, the quantum dots disclosed in Patent Document 1 have the following problem. As shown in FIGS. 8(a) and 8(b), when the quantum dots 101 have substantially the same particle size, the resulting adjacent optical absorption peaks are separate from each other, and the wavelength regions where optical absorption can occur become more discrete from one another, which can increase wavelength regions where optical absorption cannot occur. Therefore, there has been a problem in that the amount of optical absorption over the entire wavelength region including discrete energy levels still remains small.

It is an object of the present invention, which has been accomplished in view of the above problems, to provide a quantum dot solar cell capable of absorbing a large amount of light.

### Means for Solving the Problems

The present invention is directed to a quantum dot solar cell including a quantum dot layer including a plurality of quantum dots, the quantum dot layer including a first quantum dot layer having an index σ/x of 5% or more, wherein x is an average particle size of the quantum dots, σ is a standard deviation of the quantum dots, and the index σ/x indicates variations in particle size.

### Effects of the Invention

The present invention makes it possible to obtain a quantum dot solar cell capable of absorbing a large amount of light.

### BRIEF DESCRIPTION OF THE DRAWINGS

FIG. 1(a) is a cross-sectional schematic view showing an embodiment of a quantum dot solar cell, and FIG. 1(b) is an exemplary graph showing the optical absorption properties of a quantum dot solar cell with the index σ/x=10%.

FIG. 2 is an exemplary graph showing the optical absorption properties of a quantum dot solar cell with the index σ/x=20%.

FIG. 3 is a schematic diagram showing the voltage-current characteristics of a quantum dot solar cell.

FIGS. 4(a), 4(b), 4(c), 4(d), and 4(e) are schematic diagrams showing a case where the quantum dots are spherical, polyhedral, columnar, oval-spherical, and tetrapod-shaped, respectively.

FIG. 5 is a cross-sectional schematic view showing another mode of a quantum dot solar cell, which includes a first quantum dot layer and a second quantum dot layer that is provided on the light entrance surface of the first quantum dot layer and includes quantum dots whose average particle size and particle size variation are smaller than those of the quantum dots in the first quantum dot layer.

FIG. 6(a) is a cross-sectional schematic view showing another mode of a quantum dot solar cell, which includes a first quantum dot layer and a second quantum dot layer provided on the light exit surface of the first quantum dot layer, and FIG. 6(b) is a schematic diagram showing the band structure of the quantum dot solar cell shown in FIG. 6(a).

FIG. 7 is a cross-sectional schematic view showing another mode of a quantum dot solar cell, which includes a first quantum dot layer and second quantum dot layers provided on the light entrance surface and the light exit surface of the first quantum dot layer.

FIG. 8(a) is a cross-sectional view schematically showing a conventional quantum dot solar cell, and FIG. 8(b) is an exemplary graph showing the optical absorption properties of the quantum dot solar cell of FIG. 8(a).

### EMBODIMENTS FOR CARRYING OUT THE INVENTION

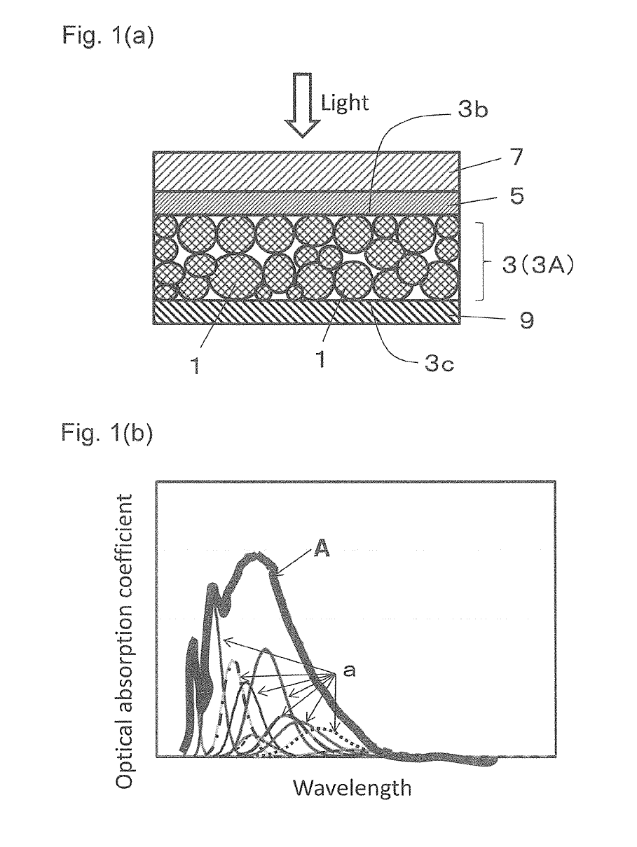

FIG. 1(a) is a cross-sectional schematic view showing an embodiment of a quantum dot solar cell, and FIG. 1(b) is an exemplary graph showing optical absorption properties of a quantum dot solar cell with the index σ/x=10% . In FIG. 1(b), symbol a indicates optical absorption coefficient curves based on various interband transitions, and symbol A indicates an optical absorption coefficient curve as the sum of the optical absorption curves indicated by symbol a.

The quantum dot solar cell of this embodiment includes a quantum dot layer 3 including a plurality of quantum dots 1. FIG. 1(a) shows an exemplary structure in which a transparent conductive film 5 and a glass substrate 7 are stacked on the light entrance surface 3b of the quantum dot layer 3 while a metal electrode 9 is provided on its light exit surface 3c opposite thereto.

In this embodiment, the quantum dot layer 3 includes a first quantum dot layer 3A including quantum dots 1 having an average particle size x and a standard deviation σ, in which the first quantum dot layer 3A has an index σ/x of 5% or more, wherein x is the average particle size of the quantum dots 1, σ is the standard deviation of the quantum dots 1, and the index σ/x indicates variations in particle size.

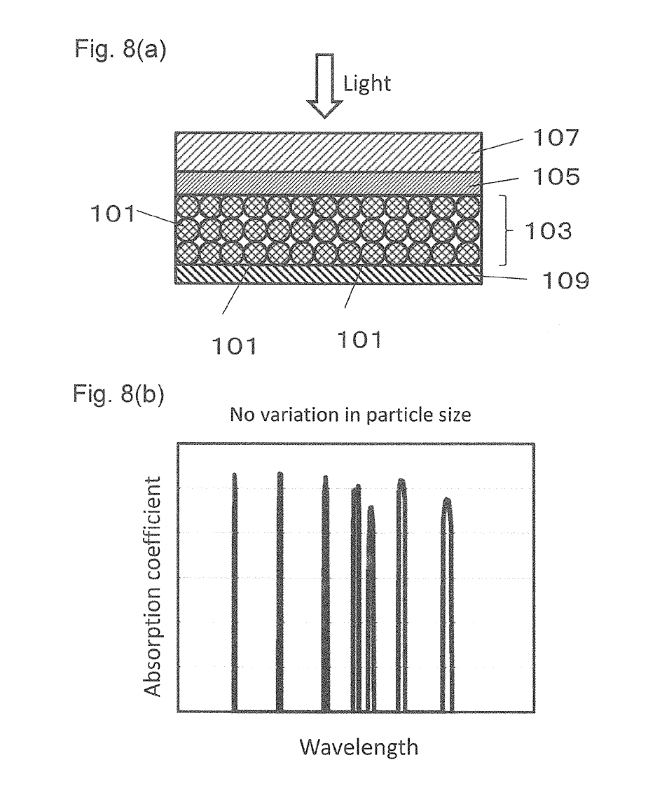

When the quantum dot layer 3 includes the first quantum dot layer 3A having a particle size variation equal to or more than the specified value, the resulting optical absorption properties are such that absorption peaks at light wavelengths are less discrete and become broad as adjacent optical absorption coefficient peaks overlap as shown in FIG. 1(b), as compared with those of a conventional quantum dot solar cell having quantum dots 101 with substantially the same particle size as shown in FIG. 8. As a result, wavelength regions where optical absorption cannot occur are reduced, which makes it possible to increase the total amount of optical absorption obtained by summing the respective optical absorption coefficient peaks. This allows the quantum dot solar cell to have an increased short circuit current (Isc). Note that the fact that the optical absorption coefficient curve A is the sum of the optical absorption curves indicated by symbol a is supported by the occurrence of a plurality of peaks at different wavelengths in the optical absorption coefficient curve A.

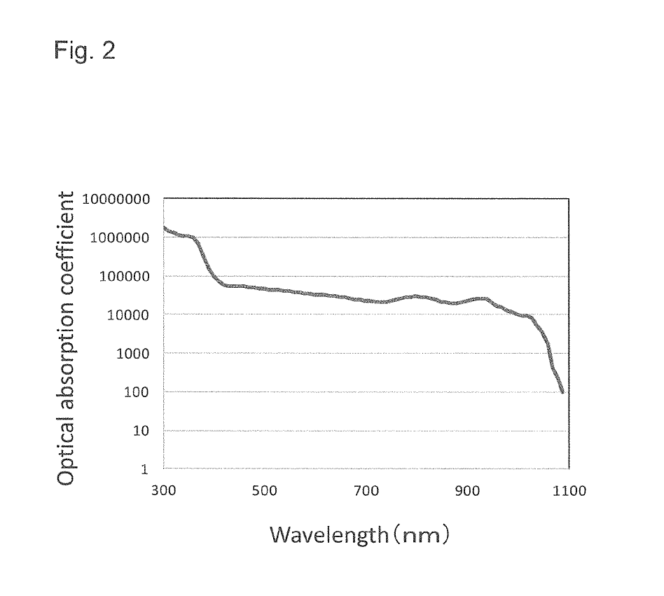

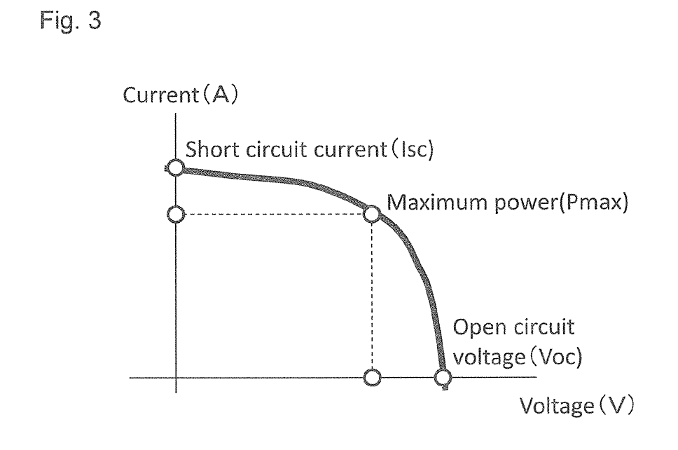

FIG. 2 is an exemplary graph showing the optical absorption properties of a quantum dot solar cell with the index σ/x=20%. FIG. 3 is a schematic diagram showing the voltage-current characteristics of a quantum dot solar cell. These are obtained when the quantum dots 1 are made of PbS and have a polyhedral shape. In FIG. 3, the short circuit current (Isc) is defined as the maximum current value obtained when the voltage is 0 V, and the open circuit voltage (Voc) is defined as the maximum voltage obtained when the current value is 0 A. The maximum power (Pmax) is defined as the maximum product of the voltage and the current inside the curve showing the voltage-current characteristics.

In this case, increasing the index σ/x to 20% makes it possible to increase the optical absorption coefficient, particularly on the long wavelength side as shown in FIG. 2, in the wavelength region where light absorption occurs, so that the resulting quantum dot solar cell can have a high optical absorption coefficient over a wide wavelength range. Thus, the index σ/x is preferably 21% or more so that the optical absorption coefficient on the long wavelength side can be increased as mentioned above. FIG. 2 with the vertical axis on a logarithmic scale shows that the optical absorption coefficient in the wavelength range of 500 to 900 nm falls within the range of 10,000 to 100,000 while the range of changes in the optical absorption coefficient is kept at 80,000 or less.

The quantum dots 1 should preferably be made to vary in particle size in order to make the optical absorption coefficient peaks less discrete and to reduce wavelength regions where optical absorption cannot occur. However, as variations in the particle size of the quantum dots increase, the absolute value of the optical absorption coefficient at each wavelength tends to decrease, so that the short circuit current (Isc) can significantly decrease. From this point of view, the index σ/x is preferably 35% or less.

The average particle size (x) and particle size variation (σ/x) of the quantum dots 1 are determined by image analysis of a photograph that is taken of a cut surface of the quantum dot layer 3 using a transmission electron microscope. The average particle size (x) is determined by drawing a circle containing 20 to 50 quantum dots 1 in the photograph, determining the contour area of each of the quantum dots 1, then calculating the diameter from each contour area, and calculating the average of the calculated diameters. The particle size variation (σ/x) is determined by calculating the standard deviation (σ) from the data obtained when the average particle size (x) is determined and then calculating σ/x.

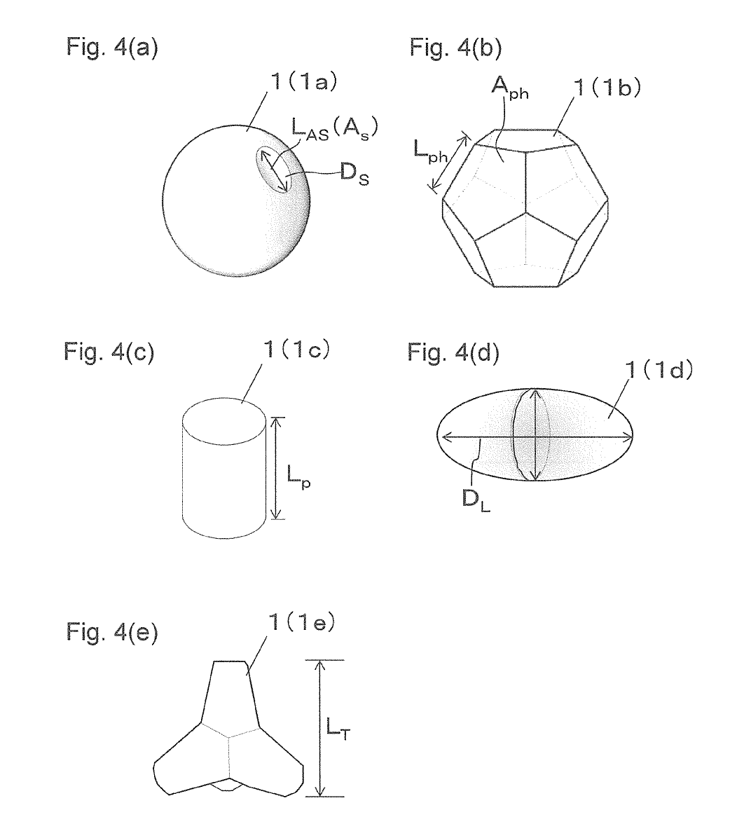

In the quantum dot solar cell of this embodiment, for example, the quantum dots 1 used may have any of various different outer shapes. FIGS. 4(a) to 4(e) show outer shapes for the quantum dots 1. FIGS. 4(a), 4(b), 4(c), 4(d), and 4(e) show a case where the quantum dots are spherical, polyhedral, columnar, oval-spherical, and tetrapod-shaped, respectively. In this case where the outer shape of the quantum dots 1 is classified into, for example, a spherical shape, a polyhedral shape, a columnar shape, an oval-spherical shape, and a tetrapod shape, the quantum dot layer 3 is preferably such that almost all of the dots arranged over the entire quantum dot layer 3 have only one of these shapes. In addition, the quantum dot solar cell preferably contains, as some of the quantum dots 1, deformed quantum dots la having a partially deformed contour.

The quantum dot layer 3 including, as base components, quantum dots 1 having substantially the same outer shape can be made dense with the contours of the quantum dots 1 regularly arranged, so that the resulting quantum dot layer 3 can have a highly continuous conduction band where carriers can move. In addition, when the quantum dot layer 3 further contains deformed quantum dots 1a having a partially deformed contour shape, the whole of the resulting film can absorb light in a wider wavelength range because the deformed quantum dots 1a in the quantum dot layer 3 have a particle size (surface area) different from that of the quantum dots 1 except the deformed quantum dots 1a. Thus, the total amount of optical absorption can be further increased.

Now, the deformed quantum dots will be described. When the quantum dots 1 have a spherical outer shape as shown in FIG. 4(a), the deformed quantum dots 1a may have a spherical shape whose surface has a concave portion D_{S}. In this case, there may be deformed quantum dots 1a different in the maximum length L_{AS} of the opening of the concave portion D_{S}.

For example, a region with a predetermined area containing about 50 quantum dots 1 (which may include deformed quantum dots 1a) is selected in a photograph taken of a cut surface of the quantum dot layer 3. In this region, a measurement is made of the maximum length L_{AS} of the opening of each concave portion D_{S} formed in the deformed quantum dot 1a. When variations in the evaluated maximum length L_{AS} are 10% or more, it is determined that there are deformed quantum dots 1a different in the maximum length L_{AS} of the opening of the concave portion D_{S}.

In the quantum dot solar cell of this embodiment, the quantum dots 1 in the first quantum dot layer 3A may include a plurality of spherical quantum dots 1 having a concave portion D_{S} on the surface and being different in the maximum length L_{AS} of the opening of the concave portion D_{S}.

When the quantum dots 1 have a polyhedral outer shape as shown in FIG. 4(b), the deformed quantum dots 1b may have flat faces Aₚₕ with different areas on the surface.

In this case, the area of the flat face Aₚₕ is evaluated by measuring the length Lₚₕ of one side of the flat face Aₚₕ observed on each of the quantum dots 1 and the deformed quantum dots 1b when the quantum dot layer 3 is observed.

For example, a region with a predetermined area containing about 50 quantum dots 1 (which may include deformed quantum dots 1b) is selected in a photograph taken of a cut surface of the quantum dot layer 3. In this region, a measurement is made of the length Lₚₕ of one side of the flat face Aₚₕ formed on each of the quantum dots 1 (including the deformed quantum dots 1b). When variations in the evaluated length Lₚₕ of one side are 10% or more, it is determined that polyhedral quantum dots 1 differ in the area of the flat face Aₚₕ.

When the quantum dots 1 have a columnar outer shape as shown in FIG. 4(c), the deformed quantum dots 1c may have different axial direction lengths Lₚ. In this case, the term “columnar” is intended to also include shapes, so called nanowires, with a major axis/minor axis ratio (aspect ratio (Lₚ/Dₚ)) as high as 10 or more. In this case, the length Lₚ of the columnar quantum dots 1 is evaluated by measuring the length Lₚ of each quantum dot 1 when the quantum dot layer 3 is observed. For example, a region with a predetermined area containing about 50 quantum dots 1 is selected in a photograph taken of a cut surface of the quantum dot layer 3. In this region, a measurement is made of the length Lₚ of each quantum dot 1. When the quantum dot 1 is curved, the length Lₚ is measured as the straight distance between both ends of the quantum dot 1. When variations in the evaluated length Lₚ are 10% or more, it is determined that columnar quantum dots 1 differ in the length Lₚ.

When the quantum dots 1 have an oval-spherical outer shape as shown in FIG. 4(d), the deformed quantum dots 1d may have different long diameters D_{L}. In this case, the long diameter D_{L} of the oval-spherical quantum dots 1 is evaluated by measuring the long diameter D_{L} of each quantum dot 1 when the quantum dot layer 3 is observed. For example, a region with a predetermined area containing about 50 quantum dots 1 is selected in a photograph taken of a cut surface of the quantum dot layer 3. In this region, the long diameter D_{L} of each quantum dot 1 is determined. When variations in the evaluated length D_{L} are 10% or more, it is determined that oval-spherical quantum dots 1 differ in the long diameter D_{L}.

When the quantum dots 1 have a tetrapod outer shape as shown in FIG. 4(e), the deformed quantum dots 1e may have different maximum diameters L_{T}. In this case, the maximum diameter L_{T} of the tetrapod-shaped quantum dots 1 is evaluated by measuring the maximum diameter L_{T} as the length of the longest portion of each tetrapod-shaped quantum dot 1 when the quantum dot layer 3 is observed. For example, a region with a predetermined area containing about 50 quantum dots 1 is selected in a photograph taken of a cut surface of the quantum dot layer 3. In this region, the maximum diameter L_{T} is measured as the length of the longest portion of each quantum dot 1. When variations in the evaluated maximum diameter L_{T} are 10% or more, it is determined that tetrapod-shaped quantum dots 1 differ in the maximum diameter L_{T}.

The quantum dots 1 (including the deformed quantum dots 1a, 1b, 1c, 1d, and 1e (hereinafter also expressed as 1a to 1e) in this case) forming the quantum dot solar cell are each composed mainly of a semiconductor particle, which preferably has a band gap (Eg) of 0.15 to 2.0 eV. Specifically, the material used to form the quantum dots 1 preferably includes any one selected from germanium (Ge), silicon (Si), gallium (Ga), indium (In), arsenic (As), antimony (Sb), copper (Cu), iron (Fe), sulfur (S), lead (Pb), tellurium (Te), and selenium (Se), or a compound semiconductor of any of them. Among them, preferred is one selected from the group of Si, GaAs, InAs, PbS, PbSe, CdSe, CdTe, CuInGaSe, CuInGaS, CuZnGaSe, and CuZnGaS. Among these semiconductor materials, examples of the material that may be used to form the spherical quantum dots 1 and the deformed spherical quantum dots 1a include Si, GaAs, InAs, CuInGeSe, CuInGaS, CuZnGaSe, and CuZnGaS. Examples of the material that may be used to form the polyhedral quantum dots 1 include PbS, PbSe, and CdSe. Examples of the material that may be used to form the columnar quantum dots 1 include Si, GaAs, and InAs. Examples of the material that may be used to form the oval-spherical quantum dots 1 include Si, GaAs, InAs, CuInGaSe, CuInGaS, CuZnGaSe, and CuZnGaS. Examples of the material that may be used to form the tetrapod-shaped quantum dots include CdTe.

In this case, as to the size of the quantum dots 1 and the deformed quantum dots 1a to 1e, they preferably have, for example, a maximum diameter of 2 nm to 10 nm (although the size in this case is the maximum diameter, the size of nanowires should be their length (diameter) in a direction perpendicular to their axial direction).

A barrier layer may be provided around the quantum dot 1. In this case, the barrier layer is preferably made of a material having a band gap 2 to 15 times higher than that of the quantum dots 1 and the deformed quantum dots 1a to 1e and having a band gap (Eg) of 1.0 to 10.0 eV. The barrier layer is preferably made of a compound (semiconductor, carbide, oxide, or nitride) containing at least one element selected from Si, C, Ti, Cu, Ga, S, In, and Se.

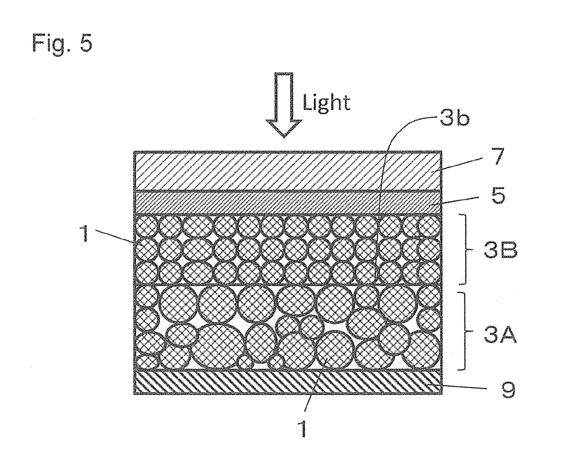

FIG. 5 is a cross-sectional schematic view showing another mode of the quantum dot solar cell, which includes the first quantum dot layer 3A and a second quantum dot layer 3B that is provided on the light entrance surface 3b of the first quantum dot layer 3A and includes quantum dots 1 whose average particle size (x) and particle size variation (index σ/x) are smaller than those of the quantum dots 1 in the first quantum dot layer 3A.

The quantum dot solar cell of this embodiment has the basic structure shown in FIG. 1, which includes a group of quantum dots (the first quantum dot layer 3A in this case) with a relatively large particle size variation. When a second quantum dot layer 3B including quantum dots 1 whose average particle size (x) and particle size variation (σ/x) are smaller than those of the quantum dots 1 in the first quantum dot layer 3A of the basic structure is formed on the light entrance surface 3b of the first quantum dot layer 3A, the resulting structure has a larger-band-gap quantum dot layer (the second quantum dot layer 3B in this case) on the light entrance surface 3b. This feature makes it possible to increase the open circuit voltage (Voc) in the voltage-current characteristics dependent on the band gap. As a result, the maximum power (Pmax) of the quantum dot solar cell can be increased. In this case, the quantum dot solar cell preferably has a particle size variation difference of 3% or more (an index σ/x difference of 3% or more in this case) between the first quantum dot layer 3A including quantum dots 1 with a relatively large particle size variation (σ/x) and the second quantum dot layer 3B including quantum dots 1 with a relatively small particle size variation (σ/x). In addition, the quantum dot solar cell preferably has an average particle size difference of 0.5 nm or more between them.

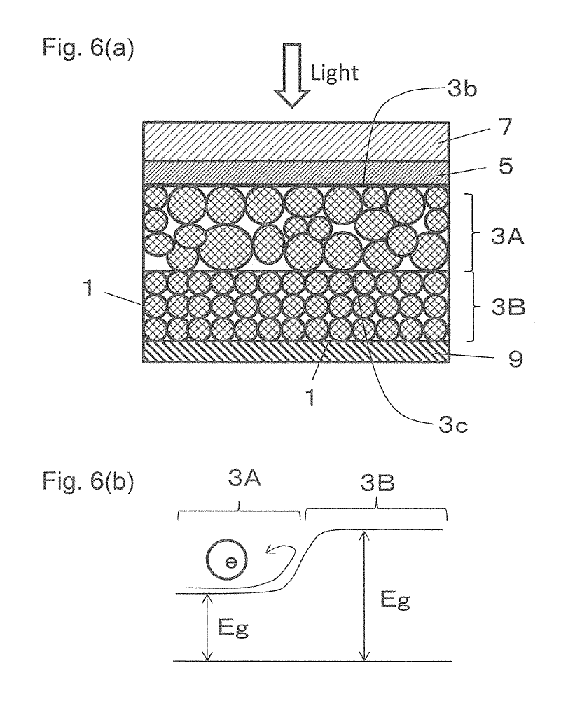

FIG. 6(a) is a cross-sectional schematic view showing another mode of the quantum dot solar cell, which includes the first quantum dot layer 3A and the second quantum dot layer 3B provided on the light exit surface 3c of the first quantum dot layer 3A. FIG. 6(b) is a schematic diagram showing the band structure of the quantum dot solar cell shown in FIG. 6(a).

In contrast to the quantum dot solar cell shown in FIG. 5, when the second quantum dot layer 3B including quantum dots 1 with a relatively small particle size variation (σ/x) is disposed on the light exit surface 3c of the first quantum dot layer 3A, the band gap (Eg) of the second quantum dot layer 3B is larger than the band gap (Eg) of the first quantum dot layer 3A as shown in FIG. 6(b). Therefore, the second quantum dot layer 3B having a band gap (Eg) larger than that of the first quantum dot layer 3A acts as an energy barrier so that the electrons e generated in the first quantum dot layer 3A are prevented from moving to the light exit surface 3c side. Therefore, the electrons e generated in the first quantum dot layer 3A can be selectively transferred to the light entrance surface 3b side, so that the quantum dot solar cell can have an increased short circuit current (Isc).

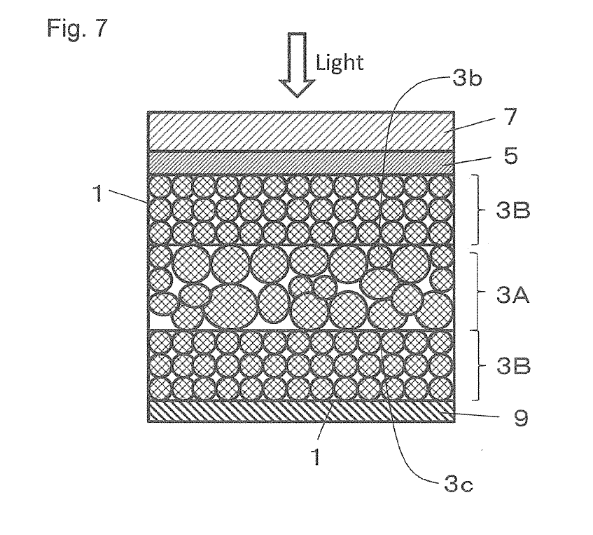

FIG. 7 is a cross-sectional schematic view showing another mode of the quantum dot solar cell, which includes the first quantum dot layer 3A and the second quantum dot layers 3B provided on the light entrance surface 3b and the light exit surface 3c of the first quantum dot layer 3A.

When the second quantum dot layers 3B are disposed on both the light entrance surface 3b and the light exit surface 3c of the first quantum dot layer 3A as shown in FIG. 7, the resulting structure makes it possible to achieve both the effect of the second quantum dot layer 3B in the structure shown in FIG. 5 and the effect of the second quantum dot layer 3B in the structure shown in FIG. 6, so that the resulting quantum dot solar cell can have both a high open circuit voltage (Voc) and a high short circuit current (Jsc). In this case, the fill factor (FF) can also be increased.

Next, a method for producing the solar cell of this embodiment will be described.

First, a glass substrate 7 is provided, and a transparent conductive film 5 including ITO as a main component is formed in advance on the surface of the substrate 7. Quantum dots 1 are preferably formed using, for example, a method that includes applying light of a specific wavelength to the semiconductor material to leach out fine particles from the semiconductor material. The average particle size (x) and particle size variation (σ/x) of the semiconductor fine particles for use as quantum dots 1 are controlled by the wavelength and power of the applied light. Deformed quantum dots 1a to 1e with a partially deformed contour shape are formed by controlling the application of light in such a manner that the wavelength of the applied light is changed within a certain range at regular time intervals.

Subsequently, the prepared semiconductor fine particles are applied to the surface of the transparent conductive film 5 formed on the surface of the glass substrate 7 to perform densification process. The method of application is preferably selected from methods of applying a solution containing the semiconductor fine particles by spin coating, sedimentation, or other techniques. After the semiconductor fine particles are applied to the surface of the transparent conductive film, the particles are subjected to a densification process using heating, pressurizing, or a method of performing heating and pressuring simultaneously. The thickness of the resulting quantum dot layer is controlled by the amount of deposited semiconductor fine particles. When the quantum dot layer 3 is formed to have a multilayer structure, the application is preferably performed in such a manner that semiconductor fine particles with different average particle sizes (x) or different particle size variations (σ/x) are stacked together.

Finally, a metal electrode 9 is formed on the upper surface of the quantum dot layer 3, and optionally a substrate is placed thereon and bonded thereto, so that the quantum dot solar cell of this embodiment shown in FIG. 1(a) can be obtained. Although the quantum dot solar cell shown in FIG. 1(a) has been described by way of example, the quantum dot solar cells shown in FIGS. 5 to 7 can also be obtained using similar production methods.

As described below, quantum dot solar cells with the structure shown in FIG. 1 were specifically prepared using different semiconductor materials as shown in Table 1 and then evaluated.

First, a glass substrate was provided, and a transparent conductive film including ITO as a main component was formed in advance on the surface of the glass substrate.

Subsequently, semiconductor fine particles, which were prepared in advance, were applied by spin coating to the surface of the transparent conductive film formed on the surface of the glass substrate, and then subjected to a densification process by heating to form a quantum dot layer. In this process, the thickness of the quantum dot layer was controlled to about 0.5 Quantum dots were prepared using a method including applying light of a specific wavelength to each semiconductor material to leach out fine particles from the semiconductor material. In this process, quantum dots 1 including deformed quantum dots 1a to 1e with a partially deformed contour shape were formed by controlling the application of light in such a manner that the wavelength of the applied light was changed within a certain range at regular time intervals.

Finally, a metal electrode of Au was formed on the upper surface of the quantum dot layer using vapor deposition. A quantum dot solar cell with a surface area of 10 mm×10 mm was prepared in this way. Three solar cell samples were prepared for each type and then subjected to the evaluations shown in Table 1.

The average particle size (x) and the average particle size variation (σ/x) of the quantum dots were determined from a photograph obtained by observation of a cut surface of the prepared quantum dot layer with a transmission electron microscope. In this process, a circle containing about 50 quantum dots was drawn, in which a circle-equivalent diameter is calculated from the contour of each quantum dot, and then the average (x) of the calculated diameters was calculated. The standard deviation (σ) was also calculated from the resulting circle-equivalent diameters, and then the variation (index σ/x) was calculated.

In addition, deformed quantum dots having a partially deformed outer shape or a partially deformed contour were extracted from the same observation photograph. Whether spherical quantum dots included deformed quantum dots was determined from variations in the measured maximum length L_{AS} of the concave portion D_{S}. Whether polyhedral quantum dots included deformed quantum dots, whether columnar quantum dots included deformed quantum dots, whether oval-spherical quantum dots included deformed quantum dots, and whether tetrapod-shaped quantum dots included deformed quantum dots were determined from variations in the measured length Lₚₕ of one side of the flat face Aₚₕ, variations in the measured length L_{P}, variations in the measured long diameter D_{L}, and variations in the measured maximum diameter L_{T}, respectively.

Among the samples shown in Table 1, samples each having quantum dots with a particle size variation (σ/x) of 5% or more all had a variation of 10 to 12% in the maximum length L_{AS} of the concave portion D_{S} of the spherical quantum dots, in the length Lₚₕ of the flat face Aₚₕ of the polyhedral quantum dots, in the length Lₚ of the columnar quantum dots, in the long diameter D_{L} of the oval-spherical quantum dots, and in the maximum diameter L_{T} of the tetrapod-shaped quantum dots.

The optical absorption coefficient was evaluated in the wavelength range of 300 to 1,100 nm using a spectrometer, and the wavelength range was determined from changes in the optical absorption coefficient.

The short circuit current (Isc) was measured in the form of short circuit current density using a solar simulator.

TABLE 1

| | Quantum dot | | | | | | | |
|---|---|---|---|---|---|---|---|---|
| | | | | | Average | Variation in | | Short circuit |
| | | | | Deformed | particle | particle size | Wavelength | current density |
| Sample | Main | Manufacturing | | quantum | size ^{##} | (length) (σ/x) | range * | (Jsc) |
| No. | component | method^{#} | Shape | dot | nm | % | nm | mA/cm² |
| 1 | Si | Light etching | Spherical | Absent | 10 | 2 | 140 | 35.3 |
| | | method | | | | | | |
| 2 | Si | Light etching | Spherical | Present | 7 | 5 | 285 | 34.8 |
| | | method | | | | | | |
| 3 | Si | Light etching | Spherical | Absent | 6 | 2 | 100 | 6.8 |
| | | method | | | | | | |
| 4 | Si | Light etching | Spherical | Present | 5 | 10 | 600 | 15 |
| | | method | | | | | | |
| 5 | Si | Light etching | Spherical | Present | 5 | 20 | 630 | 16.5 |
| | | method | | | | | | |
| 6 | Si | Light etching | Spherical | Present | 5 | 23 | 710 | 15.2 |
| | | method | | | | | | |
| 7 | Si | Light etching | Spherical | Present | 3 | 30 | 720 | 10.4 |
| | | method | | | | | | |
| 8 | Si | Light etching | Oval-spherical | Present | 6 | 35 | 680 | 29.4 |
| | | method | | | | | | |
| 9 | Si | Thin layer | Columnar | Present | 6 | 10 | 300 | 12 |
| | | laminating | | | | | | |
| 10 | Si | VLS method | Wire-shaped | Present | (110) | 23 | 500 | 25 |
| 11 | PbS | Solution mixing | Polyhedral | Present | 9 | 12 | 270 | 19 |
| | | method | | | | | | |
| 12 | PbS | Solution mixing | Polyhedral | Present | 9 | 20 | 470 | 36 |
| | | method | | | | | | |
| 13 | PbS | Solution mixing | Polyhedral | Present | 9 | 21 | 480 | 37 |
| | | method | | | | | | |
| 14 | PbS | Solution mixing | Polyhedral | Present | 6 | 22 | 320 | 20.7 |
| | | method | | | | | | |
| 15 | PbS | Solution mixing | Polyhedral | Present | 4 | 30 | 290 | 21 |
| | | method | | | | | | |
| 16 | PbSe | Colloid method | Polyhedral | Present | 12 | 10 | 280 | 35 |
| 17 | PbSe | Solution mixing | Wire-shaped | Present | (150) | 28 | 600 | 35 |
| | | method | | | | | | |
| 18 | CdTe | Colloid method | Tetrapod-shaped | Present | 45 | 40 | 660 | 28 |

^{#}VLS method (vapor-liquid-solid growth method)
^{##} It corresponds to the length when the quantum dots are wire-shaped.
* The wavelength range is such that changes in the optical absorption coefficient are within 1 decade.

The results in Table 1 show that samples each having quantum dots with a particle size variation (index σ/x) of 5% or more (sample Nos. 2 and 4 to 18) all had an optical absorption coefficient wavelength range of 270 nm or more and showed high optical absorption properties over a wide wavelength range in contrast to samples each having quantum dots with a particle size variation (index σ/x) of less than 5% (sample Nos. 1 and 3).

### DESCRIPTION OF THE REFERENCE NUMERAL

1: Quantum dot

3: Quantum dot layer

3A: First quantum dot layer

3B: Second quantum dot layer

3b: Light entrance surface

3c: Light exit surface

5: Transparent conductive film

7: Glass substrate

9: Metal electrode

1. A quantum dot solar cell comprising:
a quantum dot layer comprising a plurality of quantum dots,
the quantum dot layer comprising a first quantum dot layer having an index σ/x of 5% or more, wherein x is an average particle size of the quantum dots, σ is a standard deviation of the quantum dots, and the index σ/x indicates variations in particle size.

2. The quantum dot solar cell according to claim 1, wherein the quantum dots have an outer shape selected from the group consisting of a spherical shape, a polyhedral shape, a columnar shape, an oval-spherical shape, and a tetrapod shape.

3. The quantum dot solar cell according to claim 2, wherein the quantum dots in the first quantum dot layer include deformed quantum dots having a partially deformed contour.

4. The quantum dot solar cell according to claim 3, wherein the quantum dots have a spherical outer shape, and the deformed quantum dots have a spherical outer shape having a concave portion on a surface.

5. The quantum dot solar cell according to claim 4, wherein the deformed quantum dots include deformed quantum dots different in a maximum length of an opening of the concave portion.

6. The quantum dot solar cell according to claim 3, wherein the quantum dots have a polyhedral outer shape, and the deformed quantum dots have a polyhedral outer shape and have flat faces with different areas on a surface.

7. The quantum dot solar cell according to claim 6, wherein the deformed quantum dots include deformed quantum dots different in one side length of the flat face.

8. The quantum dot solar cell according to claim 3, wherein the quantum dots have a columnar outer shape, and the deformed quantum dots have columnar outer shapes different in axial direction length.

9. The quantum dot solar cell according to claim 3, wherein the quantum dots have an oval-spherical outer shape, and the deformed quantum dots have oval-spherical outer shapes different in long diameter.

10. The quantum dot solar cell according to claim 3, wherein the quantum dots have a tetrapod outer shape, and the deformed quantum dots have tetrapod outer shapes different in maximum diameter.

11. The quantum dot solar cell according to claim 1, wherein the quantum dots of the first quantum dot layer comprise a plurality of quantum dots each having a concave portion on a surface and having spherical shapes different in a maximum length of an opening of the concave portion.

12. The quantum dot solar cell according to claim 1, wherein the quantum dots comprise, as a main component, one selected from the group consisting of Si, GaAs, InAgs, PbS, PbSe, CdSe, CdTe, CuInGeSe, CuInGeS, CuZnGeSe, and CuZnGeS.

13. The quantum dot solar cell according to claim 1, wherein the quantum dot layer comprises a second quantum dot layer comprising quantum dots having an average particle size x and an index σ/x smaller than those of the quantum dots of the first quantum dot layer, and the second quantum dot layer is disposed on a light entrance surface of the first quantum dot layer.

14. The quantum dot solar cell according to claim 1, wherein the second quantum dot layer is disposed on a light exit surface of the first quantum dot layer.

15. The quantum dot solar cell according to claim 1, which has a plurality of peaks at different wavelengths in optical absorption coefficient curve.

16. The quantum dot solar cell according to claim 1, wherein the index σ/x is 21% or more.

17. The quantum dot solar cell according to claims 1, wherein the index σ/x is 35% or less.
